(19) United States
(12) Patent Application Publication
(10) Pub. No.: US 2019/0348631 A1
(43) Pub. Date: Nov. 14, 2019

(54) CONDUCTIVE DEVICE SUBSTRATE, METHOD FOR MANUFACTURING CONDUCTIVE DEVICE SUBSTRATE, AND DISPLAY PANEL

(71) Applicant: AU OPTRONICS CORPORATION, Hsin-chu (TW)

(72) Inventors: Chia-Wei Chen, Hsin-Chu (TW); Yu-Sheng Huang, Hsin-Chu (TW)

(21) Appl. No.: 16/520,926

(22) Filed: Jul. 24, 2019

Related U.S. Application Data
(63) Continuation of application No. 15/440,503, filed on Feb. 23, 2017.

(30) Foreign Application Priority Data
Mar. 3, 2016 (TW) 105106465

(51) Int. Cl. H01L 51/52; G02F 1/1333; H01L 51/00; H01L 27/32

(52) U.S. Cl. CPC H01L 51/5246; G02F 1/133305; H01L 51/003; G02F 2201/42; H01L 27/3244; G02F 2001/133302; G02F 2202/02; H01L 27/3276

(57) ABSTRACT

A display panel includes a conductive device substrate, which includes a substrate material layer and a conductive pillar disposed in the substrate material layer. The conductive pillar includes an organic pillar, a conductive layer, and a device layer disposed on the first surface of the conductive pillar and the substrate material layer. The conductive layer covers and is in direct contact with a top surface and side surfaces of the organic pillar. An opposite substrate is disposed opposite to the conductive device substrate. A display medium is located between the conductive device substrate and the opposite substrate. A conductive adhesive layer is disposed on and in contact with the conductive pillar. An external device is disposed facing the outer surface of the substrate material layer. The conductive pillar, the conductive adhesive layer and the external device overlap the display medium in a vertical projection direction.

### CROSS-REFERENCE TO RELATED PATENT APPLICATION

This application is a continuation application of U.S. application Ser. No. 15/440,503, filed Feb. 23, 2017, which itself claims the benefit of priority to Taiwan Patent Application No. 105106465, filed Mar. 3, 2016. The entire contents of the above identified applications are incorporated herein by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD

The present invention relates to a conductive device substrate, and in particular, to a conductive device substrate having an organic pillar.

### BACKGROUND

With advanced technology, in order to improve space utilization of panels, displays having no border or a narrow border have become an inevitable trend in the future development of the displays.

Currently, holes are drilled in the peripheral area of a substrate, a conductive material is filled in the holes and used for passing scan lines and signal lines required on a top surface of the substrate to a bottom surface of the substrate, and the space at the back of the substrate is used to reduce the required space of the peripheral area on the top surface, thereby reducing the peripheral width of a display. However, in the existing mature manufacturing process technologies of display, the manufacturing process of drilling a hole on the substrate and filling the hole with the conductive material is complex, resulting in problems such as a low yield and difficulty in realizing mass production.

In view of this, it is an objective in the art to provide an organic light-emitting display device to reduce the border width of the organic light-emitting display device.

### SUMMARY

The present disclosure provides a conductive device substrate, a method for manufacturing the conductive device substrate, and a display panel, which can effectively reduce the border space while maintaining the yield.

One aspect of the present disclosure provides a display panel, which includes: a conductive device substrate, comprising: a substrate material layer, comprising an organic material, and having an inner surface and an outer surface opposite to each other; a conductive pillar, disposed in the substrate material layer, and having a first surface and a second surface opposite to each other, wherein the first surface of the conductive pillar is exposed on the inner surface of the substrate material layer, the second surface of the conductive pillar is exposed on the outer surface of the substrate material layer, and the conductive pillar further comprises: an organic pillar, having a top surface and a bottom surface opposite to each other and a plurality of side surfaces connecting to the top surface and the bottom surface; and a conductive layer, covering and in direct contact with the top surface of the organic pillar and the side surfaces of the organic pillar; and a device layer, comprising at least one active device and disposed on the first surface of the conductive pillar and the substrate material layer, so as to be electrically connected to the first surface of the conductive pillar; an opposite substrate, disposed opposite to the conductive device substrate, wherein the inner surface of the substrate material layer faces the opposite substrate; a sealant, located between the conductive device substrate and the opposite substrate; a display medium, located between the conductive device substrate, the opposite substrate, and the sealant; a pixel electrode located on the conductive device substrate and facing the display medium; a conductive adhesive layer, disposed on the second surface of the conductive pillar and being in contact with the second surface of the conductive pillar; and an external device, disposed facing the outer surface of the substrate material layer, wherein the external device is disposed on one side of the conductive adhesive layer away from the conductive pillar and is in contact with the conductive adhesive layer. The conductive pillar, the conductive adhesive layer and the external device overlap the display medium in a vertical projection direction. The pixel electrode and the at least one active device are entirely located between the inner surface of the substrate material layer and the opposite substrate.

Based on the above, the present disclosure uses the organic pillar and the conductive layer to form the conductive pillar for allowing the top surface and the bottom surface of the conductive device substrate to be in communication with each other. Thus, the objective of electrically connecting the top surface and the bottom surface of the conductive device substrate can be achieved without the need to drill a hole and fill the hole with a conductive material, such that the process of manufacturing the conductive device substrate is simplified, and the border space can be effectively reduced while maintaining the yield.

To make the above characteristics and advantages of the present disclosure clearer and easier to understand, the following embodiments are described in detail in conjunction with accompanying figures.

### BRIEF DESCRIPTION OF THE DRAWINGS

The disclosure will become more fully understood from the detailed description given herein below for illustration only, and thus are not limitative of the disclosure, and wherein:

FIG. 1 is a schematic bottom view of a conductive device substrate according to one embodiment of the present disclosure.

FIG. 2A to FIG. 2M are schematic cross-sectional views of a manufacturing process according to a cross-sectional line A-A′ of the conductive device substrate in FIG. 1.

FIG. 3A to FIG. 3D are schematic cross-sectional views of a manufacturing process for a display panel according to one embodiment of the present disclosure.

FIG. 4A is a schematic bottom view of a conductive device substrate according to another embodiment of the present disclosure.

FIG. 4B is a schematic cross-sectional view according to a cross-sectional line B-B′ of the conductive device substrate in FIG. 4A.

FIG. 5 is a schematic cross-sectional view of a conductive device substrate according to still another embodiment of the present disclosure.

### DETAILED DESCRIPTION

The following describes the embodiments with reference to the accompanying drawings in detail, so as to make the aspects of present disclosure more comprehensible. However, the mentioned embodiments are not intended to limit the scope of present disclosure, and the description of the operation of a structure is not intended to limit an execution sequence. Any device with equivalent functions that is produced from a structure formed by a recombination of elements shall fall within the scope of present disclosure. Besides, according to industry standards and practices, the drawings are merely intended to assist the description, and are not drawn according to original dimensions. In practice, dimensions of various features may be arbitrarily increased or decreased to facilitate the description. Same elements in the description below are indicated by a same reference sign, so as to facilitate the comprehension.

In present disclosure, when an element is “connected” or “coupled”, it may indicate that the element is “electrically connected” or “electrically coupled”. “Connected” or “coupled” may further be used to indicate that two or more elements operate cooperatively or interact with each other. Oppositely, when an element is “directly on another element” or “directly connected to” another element, there is no intermediate element. As used herein, “connection” may refer to physical and/or electrical connection.

The terms used herein are merely used for describing specific embodiments, and are not limitative. As used herein, unless otherwise clearly indicated in the content, singular forms “a”, “one”, and “the” are intended to include plural forms, and include “at least one”. “Or” indicates “and/or”.

As used herein, “about”, “similar”, or “substantially” includes the value and an average value of values in an acceptable deviation range of a specific value determined by a person of ordinary skill in the art, taking the discussed measurement and a specific quantity of errors related to the measurement (that is, limitations of a measurement system) into consideration. For example, “about” may indicate within one or more standard deviations of the value, or within ±20%, ±10%, or ±5%.

Unless otherwise defined, as used herein, all the terms (including technical and scientific terms) have the same meanings as commonly understood by a person of ordinary skill in the art. It will be further understood that terms defined in commonly used dictionaries shall be comprehended as meanings the same as the meanings in the related art and the context of the present disclosure, and shall not be comprehended as ideal or excessively formal meanings, unless this specification clearly defined otherwise.

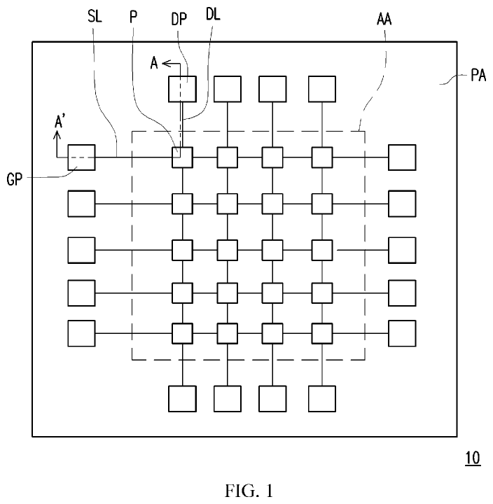

FIG. 1 is a schematic bottom view of a conductive device substrate 10 according to one embodiment of the present disclosure. Referring to FIG. 1, the conductive device substrate 10 can be divided into an active area AA and a peripheral area PA. In the active area AA, a plurality of pixel structures P (only one pixel structure is shown in the figure) are arranged in an array. Each pixel structure is electrically connected to at least one scan line SL and at least one data line DL corresponding thereto. The scan line SL and the data line DL extend from the active area AA to the peripheral area PA, so as to be electrically connected to a gate electrode pad GP and a data pad DP located within the peripheral area PA. In other words, a device (or namely component, or element) located within the pixel structure P in the active area AA can be driven by the gate electrode pad GP and the data pad DP located within the peripheral area PA by means of the scan line SL and the data line DL.

The scan line SL and the data line DL intersect each other, and an insulation layer is located between the scan line SL and the data line DL. The extension direction of the scan line SL may not be parallel to the extension direction of the data line DL, and preferably, the extension direction of the scan line SL is substantially perpendicular to the extension direction of the data line DL. In consideration of electrical conductivity, the scan line SL and the data line DL are generally made of metal materials. However, the present disclosure is not limited thereto, and according to other embodiments, the scan line SL and the data line DL may also be made of other conductive materials, for example, alloys, nitrides of above-mentioned materials, oxides of above-mentioned materials, nitroxide of above-mentioned materials (or namely nitrogen oxides of above-mentioned materials), or other suitable conductive materials, or a stacking layer of at least two of the above-mentioned materials.

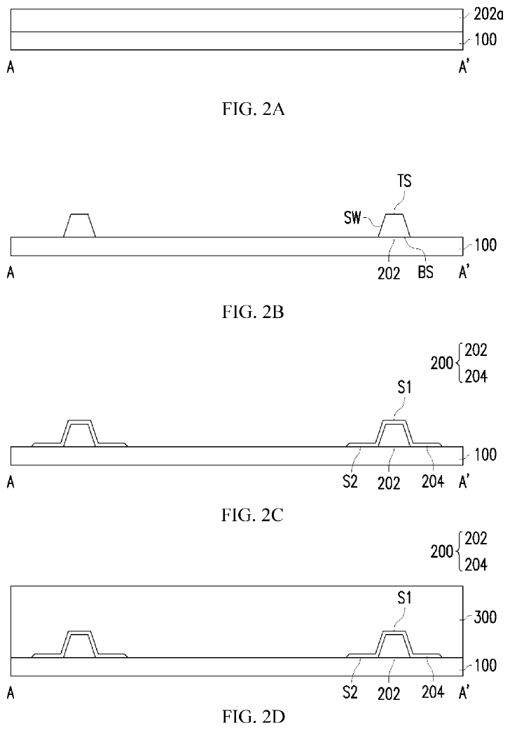

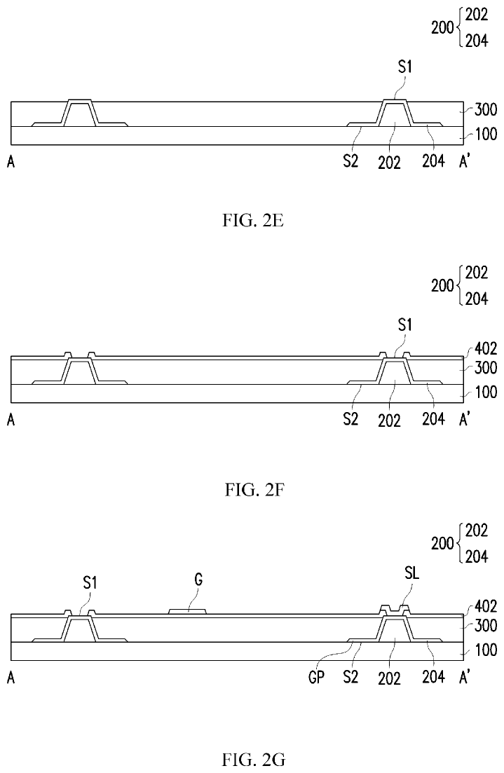

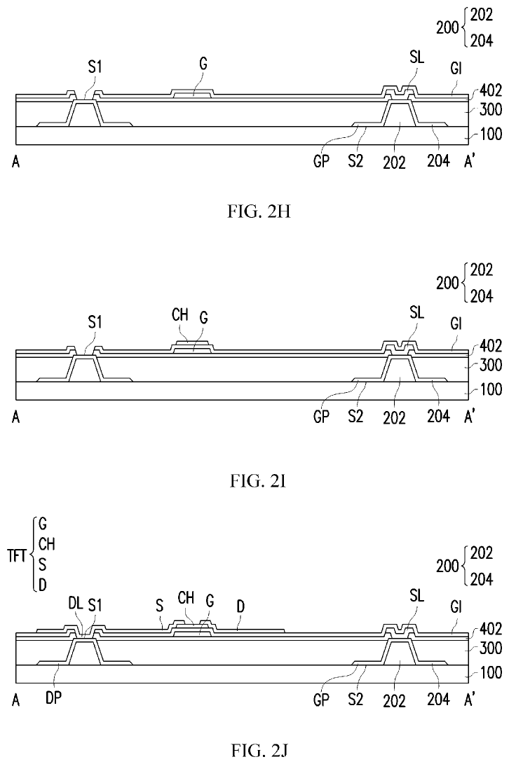

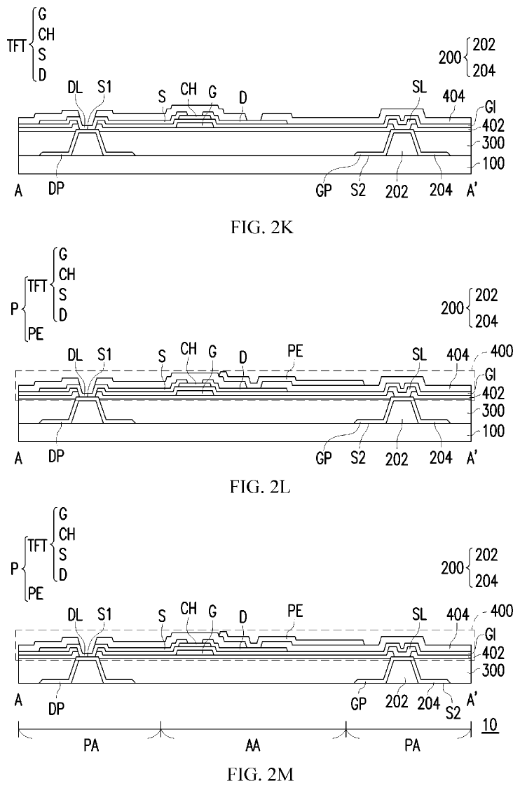

FIG. 2A to FIG. 2M are schematic cross-sectional views of a manufacturing process according to a cross-sectional line A-A′ of the conductive device substrate 10 in FIG. 1. The manufacturing process of the conductive device substrate 10 is described in detail below. Referring to FIG. 2A, first, a carrier substrate 100 is provided and an organic layer 202a is formed on the carrier substrate 100. The material of the carrier substrate 100 may be glass, quartz, an organic polymer, or an opaque/reflective material (such as a conductive material, metal, wafer, ceramic, or other suitable materials), or other suitable materials. In the present embodiment, because the carrier substrate 100 must carry the devices subsequently formed thereon, it is preferably made of a rigid material, but the present disclosure is not limited thereto. Other materials capable of carrying the devices may also be used as the carrier substrate 100 in the present disclosure. In another aspect, the method for forming the organic layer 202a includes: coating an organic polymer material (not shown) in the form of a solution on the carrier substrate 100, and curing the organic polymer material in the form of a solution by means of a method such as drying, so as to form the organic layer 202a having a thickness of about 3 μm to 10 μm on the carrier substrate 100. The organic polymer material comprises a colored or transparent photoresist, or other suitable materials, or a stacking layer of at least two of the above-mentioned materials.

Subsequently, the organic layer 202a is patterned to form a plurality of organic pillars 202, as shown in FIG. 2B. Specifically, in the present embodiment, the step of patterning may be performed by means of photolithography. The organic pillar 202 has a top surface TS and a bottom surface BS opposite to each other. In another aspect, the organic pillar 202 further has a plurality of side surfaces SW connecting to the top surface TS and the bottom surface BS. The bottom surface BS is in contact with an inner surface of the carrier substrate 100. As stated above, the material of the organic pillar 202 is not particularly limited in the present disclosure, as long as it is an organic polymer material or other materials such as other organic materials can be used to polymerizated to form the organic polymer materials.

Referring to FIG. 2C, a conductive layer 204 is formed to cover the top surface TS and the side surfaces SW of the organic pillar 202. In addition, the conductive layer 204 also extends to cover a portion of the inner surface of the carrier substrate 100, for example, the conductive layer 204 also extends to cover a portion of the inner surface of the carrier substrate 100 surrounding or near to the organic pillar 202. The material of the conductive layer 204 may be metal, an alloy, a nitride of a metal material, an oxide of a metal material, a nitroxide of a metal material, or other suitable materials, or other suitable materials, or a stacking layer of at least two of the above materials. In this step, a conductive material (not shown) having a thickness of about 0.05 μm to 0.3 μm is formed on the carrier substrate 100 and the organic pillar 202 by means of physical sputtering or chemical vapor deposition, and then the conductive material is patterned to obtain the conductive layer 204. In the present embodiment, the thickness of the conductive material mentioned above is taken as an example only, and is not intended to limit the present embodiment. In other embodiments, the thickness of the conductive material may be changed as needed. In the present embodiment, the organic pillar 202 and the conductive layer 204 constitute a conductive pillar(s) 200, and the conductive pillar 200 includes a first surface S1 and a second surface S2 opposite to each other. Because the organic pillar 202 and the conductive layer 204 are formed on the carrier substrate 100, the second surface S2 of the conductive pillar 200 is in contact with the carrier substrate 100. In addition, the shape of the first surface S1 of the conductive pillar 200 may be different from that of the second surface S2, and the cross-sectional shape and/or the projection shape of the conductive pillar 200 may also be polygonal. In the present embodiment, the conductive pillar 200 has, for example, a trapezoidal cross-sectional shape, but the present disclosure is not limited thereto.

Subsequently, referring to FIG. 2D, a substrate material layer 300 is coated to cover the conductive pillar 200 and the carrier substrate 100. The material of the substrate material layer 300 is an organic material, for example, polyimide, epoxy resin, or other suitable materials (for example, other organic materials, or inorganic materials), or a combination of at least two of the above-mentioned materials. In other words, the organic material of the substrate material layer 300 may be made of organic materials, a mixture of an organic material and an inorganic material, a material formed by bonding organic molecules and inorganic molecules, or other suitable materials. Specifically, in the present embodiment, the substrate material layer 300 in this step is a material in the form of a solution. After the substrate material layer 300 is dried and cured, the cured substrate material layer 300 has a reduced overall thickness because the solvent in the material in the form of a solution may be evaporated in the drying process, exposing the first surface S1 of the conductive pillar 200, as shown in FIG. 2E. In the present embodiment, the thickness of the substrate material layer 300 is reduced by volatilizing the solvent, but the present disclosure is not limited thereto. In other embodiments, the substrate material layer 300 may also be thinned by means of an etching process, a chemical mechanical polishing (CMP) process, or other thinning processes. It is worth noting that, in the present embodiment, the first surface (the inner surface) S1 of the conductive pillar 200 is exemplified as higher than the substrate material layer 300, but the present disclosure is not limited thereto. In other embodiments, the first surface S1 of the conductive pillar 200 may also be substantial flush (or namely substantial even, or substantial level) with the substrate material layer 300, or the first surface S1 of the conductive pillar 200 may also be substantial lower (or namely substantial even, or substantial level) than the substrate material layer 300, as long as the substrate material layer 300 can expose the first surface S1 of the conductive pillar 200. In addition, the conductive layer 204 located on two sides of the conductive pillar 200 is in direct contact with the substrate material layer 300 located at these sides.

Referring to FIG. 2F, a barrier layer 402 is formed on the substrate material layer 300. The barrier layer 402 comprises inorganic materials (for example, silicon oxide, silicon nitride, silicon oxynitride, other suitable materials, or a stacking layer of at least two of the above-mentioned materials), organic materials (for example, polyesters (PET), polyenes, polyacrylamides, polycarbonates, polyalkylene oxides, polystyrenes, polyethers, polyketones, polyols, polyaldehydes, or other suitable materials, or a combination of the above-mentioned materials), or other suitable materials, or a combination of the above-mentioned materials. In addition, the barrier layer 402 exposes at least one portions of the first surface S1 of the conductive pillar 200, for facilitating the electrical connection of the subsequently formed devices.

Thereafter, a gate electrode G and a scan line SL are formed at the same time, as shown in FIG. 2G. In other words, the gate electrode G and the scan line SL are in the same film layer. More specifically, in the present embodiment, the gate electrode G is connected to the scan line SL. Referring to FIG. 2G, the gate electrode G is located on the barrier layer 402, and the scan line SL is located on the first surface S1 of a portion of the conductive pillar(s) 200. That is to say, the scan line SL is connected to a portion of the conductive pillar(s) 200. At this time, the portion of the conductive pillar(s) 200 connected to the scan line SL may serve as a gate electrode pad GP or a scan line conductive pillar. As stated above, the materials of the scan line SL and the gate electrode G may include metal materials, alloys, nitrides of above-mentioned materials, oxides of above-mentioned materials, nitroxides of above-mentioned materials, or other suitable materials), or a stacking layer of a metal material and other conductive materials.

Referring to FIG. 2H, a gate insulation layer GI is formed on the gate electrode G and the scan line SL. The gate insulation layer GI covers the gate electrode G, the scan line SL, and the barrier layer 402. Similar to the barrier layer 402, the gate insulation layer GI also exposes the first surface S1 of the conductive pillar 200 that is not covered by the scan line SL. In another aspect, the material of the gate insulation layer GI comprises inorganic materials (for example, silicon oxide, silicon nitride, silicon oxynitride, other suitable materials, or a stacking layer of at least two of the above-mentioned materials), organic materials, or other suitable materials, or a combination of the above-mentioned materials. Subsequently, a channel layer CH is formed on the gate insulation layer GI, and the channel layer CH is located above the gate electrode G, as shown in FIG. 2I. The material of the channel layer CH may be selected from an amorphous silicon (a-Si) material, a polycrystalline silicon material, or a metal oxide semiconductor material (including indium-gallium-zinc oxide (IGZO), zinc oxide (ZnO), tin oxide (SnO), indium-zinc oxide (IZO), gallium-zinc oxide (GZO), zinc-tin oxide (ZTO), indium-tin oxide (ITO), or other suitable materials, or a combination of at least two of the above-mentioned materials), microcrystalline silicon, monocrystalline silicon, an organic semiconductor, nano-carbon tube/rod, or other suitable materials, or a combination of at least two of the above-mentioned materials.

Referring to FIG. 2J, a source electrode S, a drain electrode D, and the data line DL are formed at the same time. That is, the source electrode S, the drain electrode D, and the data line DL are in the same film layer, but the present disclosure is not limited thereto. The data line DL is connected to the source electrode S, and the source electrode S is separated from the drain electrode D. In another aspect, the data line DL is disposed on the first surface S1 of the conductive pillar 200 that is not covered by the scan line SL. In other words, the scan line SL is electrically connected to a portion of the conductive pillar(s) 200, and the data line DL is electrically connected to the rest of the conductive pillar(s) 200. At this time, the rest of the conductive pillar(s) 200 electrically connected to the data line DL may serve as a data pad DP or a data line conductive pillar. Similar to the scan line SL and the gate electrode G, the materials of the source electrode S, the drain electrode D, and the data line DL may include metal materials, alloys, nitrides of above-mentioned materials, oxides of above-mentioned materials, nitroxides of above-mentioned materials, or other suitable materials, or a stacking layer of a metal material and other conductive materials. In the present embodiment, the gate electrode G, the channel layer CH, the source electrode S, and the drain electrode D form an active device TFT. Specifically, in the present embodiment, a bottom-gate thin film transistor is taken as an example for illustration, but the present disclosure is not limited thereto. According to other embodiments, the active device TFT may also be a top-gate thin film transistor, or other suitable types of thin film transistors.

Referring to FIG. 2K, after the active device TFT is formed, an insulation layer 404 is further formed on the active device TFT. The material of the insulation layer 404 may be substantially the same as or different from that of the gate insulation layer GI. Specifically, the material of the insulation layer 404 comprises inorganic materials (for example, silicon oxide, silicon nitride, silicon oxynitride, other suitable materials, or a stacking layer of at least two of the above-mentioned materials), organic materials (for example, the above-mentioned materials), or other suitable materials, or a combination of the above-mentioned materials. In the present embodiment, the insulation layer 404 exposes a portion of the data line DL above the data pad DP and a portion of the drain electrode D. Subsequently, a pixel electrode PE is filled into the portion of the drain electrode D that is exposed by the insulation layer 404, such that the pixel electrode PE is connected to the drain electrode D, as shown in FIG. 2L. The pixel electrode PE may be a transmissive pixel electrode, a reflective pixel electrode, or a transflective pixel electrode. The material of the transmissive pixel electrode includes a metal oxide, such as indium-gallium-zinc oxide (IGZO), zinc oxide (ZnO), tin oxide (SnO), indium-zinc oxide (IZO), gallium-zinc oxide (GZO), zinc-tin oxide (ZTO), or indium-tin oxide (ITO), or other suitable oxides, or a stacking layer of at least two of the above-mentioned materials. The material of the reflective pixel electrode includes a high-reflectivity metal material.

In the present embodiment, the pixel structure P, the scan line SL, the data line DL, the barrier layer 402, the gate insulation layer GI, and the insulation layer 404 form a device layer (or namely component layer, or namely element layer) 400. Because the pixel structure P in the present embodiment includes the active device TFT, the device layer 400 in the present embodiment is exemplified as an active device array layer, but the present disclosure is not limited thereto. In other embodiments, other types of device layers (for example, a sensing device, a touch sensing device, a force sensing device, or other suitable sensing devices, or a combination of at least two of the above-mentioned devices) may also be used as the device layer 400 in the present disclosure.

Referring to FIG. 2M, the carrier substrate 100 is removed subsequently to expose the second surface S2 of the conductive pillar 200, i.e., to expose the outer surfaces of the conductive pillar 200 and the substrate material layer 300 in the substrate (for example, conductive device substrate 10). Specifically, the second surface (or namely outer surface) S2 of the conductive pillar 200 electrically connected to the scan line SL may serve as a position for the connection between the gate electrode pad GP and an external device (not shown), and the second surface S2 of the conductive pillar 200 electrically connected to the data line DL may serve as a position for the connection between the data pad DP and an external device (not shown). The external device comprises a chip, a flexible circuit board (FPC), a rigid circuit board (or namely printed circuit board, PCB), or other suitable devices, or a combination of at least two of the above devices. In the present embodiment, the method for removing the carrier substrate 100 is, for example, a laser lift-off method, but the present disclosure is not limited thereto. In other embodiments, other lift-off methods such as a mechanical lift-off method or other suitable removal methods may also be used as a method for removing the carrier substrate 100.

Upon completion of the step of FIG. 2M, the conductive device substrate 10 in the present embodiment is almost completed. Referring to FIG. 2M, the conductive device substrate 10 includes the substrate material layer 300, the conductive pillar 200, and the device layer 400. The conductive pillar 200 is disposed in the substrate material layer 300, and the substrate material layer 300 exposes the first surface (or namely the inner surface) S1 and the second surface (or namely the outer surface) S2 of the conductive pillar 200. In another aspect, the device layer 400 is disposed on the first surface S1 of the conductive pillar 200 and the substrate material layer 300. As mentioned above, because the scan line SL and the data line DL are electrically connected to the conductive pillar 200, respectively, and therefore the device layer 400 is also electrically connected to the conductive pillar 200.

In the present embodiment, the organic pillar 202 and the conductive layer 204 are used to form the conductive pillar 200 which is adapted to allow the top surface (or namely the inner surface) and the bottom surface (or namely the outer surface) of the conductive device substrate 10 to be in communication with each other. Thus, the objective of electrically connecting the top surface and the bottom surface of the conductive device substrate 10 can be achieved without the need to drill a hole and fill the hole with a conductive material, such that the process of manufacturing the conductive device substrate 10 is simplified, and the border space can be effectively reduced while maintaining the yield. In addition, because of the ductility of the substrate material layer 300, after the carrier substrate 100 is removed, the conductive device substrate 10 in the present embodiment is flexible, thus being applicable in more aspects.

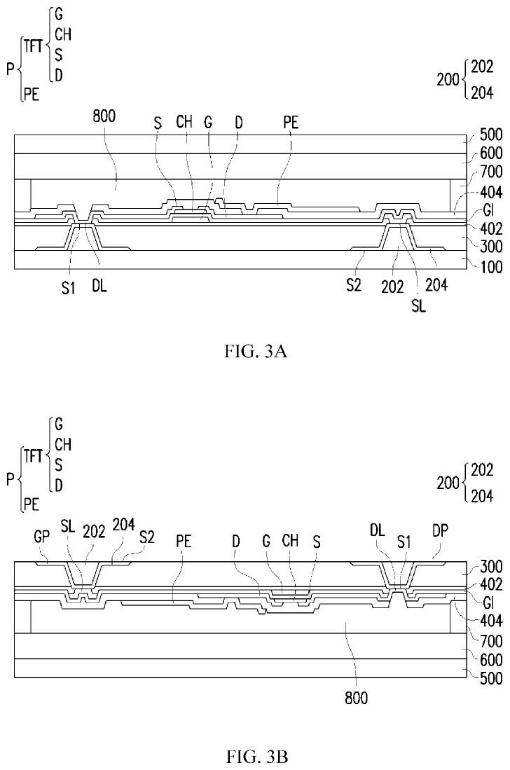

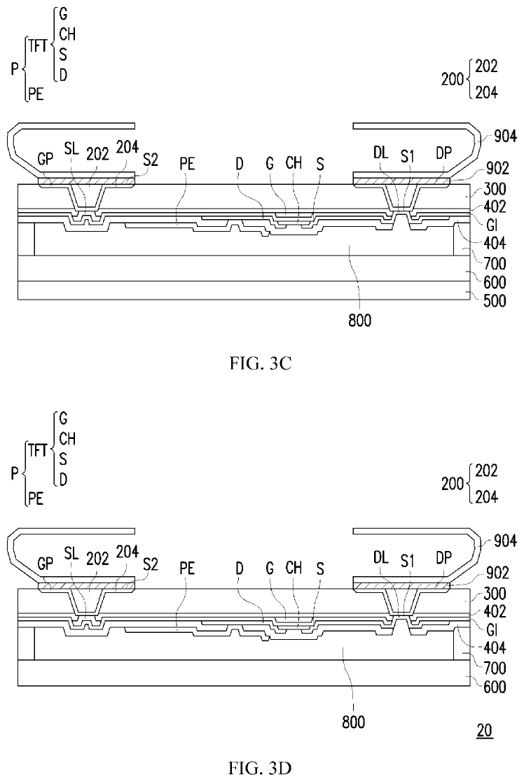

FIG. 3A to FIG. 3D are schematic cross-sectional views of a manufacturing process for a display panel 20 according to one embodiment of the present disclosure. Referring to FIG. 3A, in the present embodiment, a conductive device substrate manufactured by using the steps of FIG. 2A to FIG. 2L is provided. In other words, the present embodiment is different from the embodiment of the conductive device substrate 10 in that, after the step of FIG. 2L is completed, the step in FIG. 2M is not performed, but the step of FIG. 3A is performed first. First, an opposite carrier substrate 500 and an opposite substrate 600 are provided. The material of the opposite carrier substrate 500 may be similar to that of the carrier substrate 100, i.e., the material of the carrier substrate 500 includes glass, quartz, an organic polymer, or an opaque/reflective material (such as a conductive material, metal, wafer, ceramic, or other suitable materials), or other suitable materials. In another aspect, the material of the opposite substrate 600 may be substantially the same as or different from the material of the substrate material layer 300, such as polyimide, epoxy resin, or other suitable materials (for example, other organic materials or inorganic materials), or a combination of at least two of the above-mentioned materials. Subsequently, the opposite carrier substrate 500, the opposite substrate 600, and the conductive device substrate are assembled. Specifically, the opposite carrier substrate 500 and the opposite substrate 600 are disposed opposite to the conductive device substrate, and a sealant 700 is located between the conductive device substrate and the opposite substrate 600. In another aspect, a display medium 800 is sealed between the opposite substrate 600, the conductive device substrate, and the sealant 700. In other words, the display medium 800 is disposed in an accommodation space between the opposite substrate 600, the conductive device substrate, and the sealant 700. The material of the sealant 700 is, for example, a thermosetting adhesive, a light-cured adhesive, or other suitable materials, or a combination of the above-mentioned materials. The display medium 800 may include a liquid crystal material, an electrophoresis material, a self-luminescent material, an electro-wetting material, or other suitable materials, or a combination of at least two of the above-mentioned materials.

Referring to FIG. 3B, the structure of FIG. 3A is inverted, and the carrier substrate 100 is removed. Similar to the embodiment of FIG. 2A to FIG. 2M, the method for removing the carrier substrate 100 is, for example, a laser lift-off method, but the present disclosure is not limited thereto. In other embodiments, other lift-off methods such as a mechanical lift-off method, or other removal method may also be used as a method for removing the carrier substrate 100, and the structure in FIG. 3A may not be inverted. Subsequently, a conductive adhesive layer 902 is formed on the second surface (the outer surface) S2 of the conductive pillar 200, as shown in FIG. 3C. In other words, the conductive adhesive layer 902 is in contact with the gate electrode pad GP and the data pad DP, respectively. The conductive adhesive layer 902 is mainly formed of an adhesive and conductive particles, and the adhesive is, for example, made of a resin. In other embodiments, the conductive adhesive layer 902 comprises eutectic metal, eutectic alloy, soft metal (such as tin, aluminum, nickel, silver, gold, copper, or other suitable materials), soft alloy (such as mixture of at least two of the soft metals, or other suitable materials), or other suitable materials. After that, an external device 904 is adhered on one side of the conductive adhesive layer 902 away from the conductive pillar 200. In other words, the conductive adhesive layer 902 is located between the external device 904 and the second surface (the outer surface) S2 of the conductive pillar 200, so as to electrically connect the conductive pillar 200 and the external device 904. The external device 904 may also comprise a chip, a flexible circuit board, a rigid circuit board, or other suitable devices, or a combination of at least two of the above-mentioned devices. In the present embodiment, the external device 904 is, for example, a flexible circuit board, but the present disclosure is not limited thereto.

Subsequently, referring to FIG. 3D, the opposite carrier substrate 500 is separated from the opposite substrate 600 to complete the display panel 20. The step of removing the opposite carrier substrate 500 is similar to the step of removing the carrier substrate 100, and thus may not be repeated herein in detail.

Similar to the embodiment of FIG. 2A to FIG. 2M, in the present embodiment, the organic pillar 202 and the conductive layer 204 are used to form the conductive pillar 200 for allowing the top surface (the inner surface) and the bottom surface (the outer surface) of the conductive device substrate in the display panel 20 to be in communication with each other. Thus, the objective of electrically connecting the top surface and the bottom surface of the conductive device substrate can be achieved without the need to drill a hole and fill the hole with a conductive material, such that the process of manufacturing the conductive device substrate is simplified, and the border space can be effectively reduced while maintaining the yield. In addition, because of the ductility of the substrate material layer 300 and the opposite substrate 600, after the carrier substrate 100 and the opposite carrier substrate 500 are removed, the display panel 20 in the present embodiment is flexible, thus being applicable in more aspects.

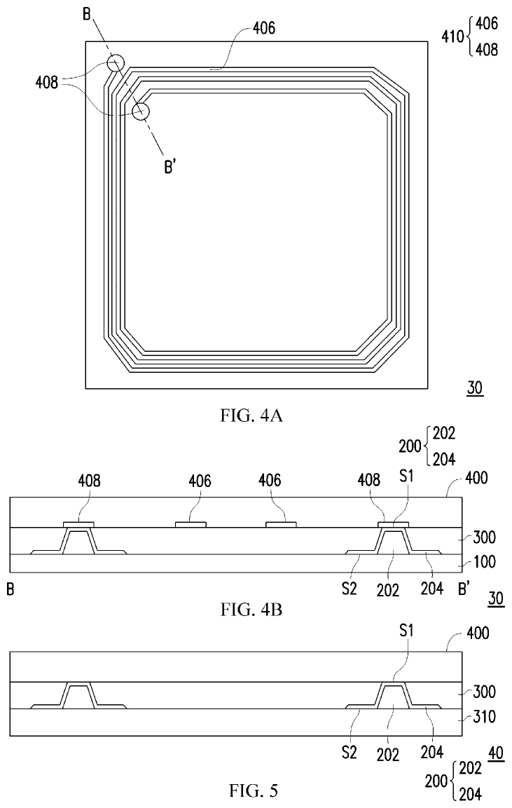

FIG. 4A is a schematic bottom view of a conductive device substrate 30 according to another embodiment of the present disclosure. FIG. 4B is a schematic cross-sectional view according to a cross-sectional line B-B′ of the conductive device substrate 30 in FIG. 4A. Referring to both FIG. 4A and FIG. 4B, the present embodiment is similar to the embodiment of FIG. 2A to FIG. 2M, such that the similar content will not be repeated herein in detail. The difference between the present embodiment and the embodiment of FIG. 2A to FIG. 2M lies in that, in the present embodiment, the device layer 400 is a wireless antenna circuit 410. The wireless antenna circuit 410 has a coil body 406 and two electrode terminals 408 respectively connected to two ends of the coil body 406. One of the two electrode terminals 408 is connected to the first surface (or namely the inner surface) S1 of a portion of the conductive pillar(s) 200 in the substrate, and the other of the two electrode terminals 408 is connected to the first surface (or namely the inner surface) S1 of the other portion of the conductive pillar(s) 200 in the substrate. Specifically, because the device layer 400 is the wireless antenna circuit 410, the signal generated thereby may be transmitted to other devices in a wireless manner. Therefore, it is unnecessary to remove the carrier substrate 100 for the subsequent processes such as wire bonding. Furthermore, in other embodiments, the coil body 406 and the electrode terminals 408 of the wireless antenna circuit 410 may be formed when a portion of the conductive pillar 200(s) forms the conductive layer 204, and the rest of the conductive pillar(s) 200 may be used as a pad for other devices subsequently, such as the gate electrode pad GP and the data pad DP.

Similar to the embodiment of FIG. 2A to FIG. 2M, in the present embodiment, the organic pillar 202 and the conductive layer 204 are used to form the conductive pillar 200 for allowing the top surface (or namely the inner surface) and the bottom surface (or namely the outer surface) of the conductive device substrate 30 to be in communication with each other. Thus, the objective of electrically connecting the top surface and the bottom surface of the conductive device substrate 30 can be achieved without the need to drill a hole and fill the hole with a conductive material, such that the process of manufacturing the conductive device substrate 30 is simplified, and the border space can be effectively reduced while maintaining the yield.

FIG. 5 is a schematic cross-sectional view of a conductive device substrate 40 according to still another embodiment of the present disclosure. Referring to FIG. 5, the present embodiment is similar to the embodiment of FIG. 4, such that the similar content will not be repeated herein in detail. The difference between the present embodiment and the embodiment of FIG. 4 lies in that, in the present embodiment, before the organic pillar 202 is formed, a step of forming an auxiliary substrate material layer 310 on the carrier substrate 100 is further included. In other words, in the present embodiment, the second surface (or namely the outer surface) S2 of the conductive pillar 200 is in contact with the inner surface of the auxiliary substrate material layer 310, instead of being in contact with the carrier substrate 100. The material of the auxiliary substrate material layer 310 may be substantially the same as or different from that of the substrate material layer 300. That is to say, the material of the auxiliary substrate material layer 310 includes, for example, polyimide, epoxy resin, or other suitable materials (for example, other organic materials, or inorganic materials), or a combination of the above-mentioned materials. Similar to the step of FIG. 2M, the present embodiment may also include a step of removing the carrier substrate 100 by means of a laser lift-off method or other suitable methods. In another aspect, similar to the embodiment of FIG. 4, because the device layer 400 is the wireless antenna circuit 410, the signal generated thereby may be transmitted to other devices in a wireless manner. Therefore, it is unnecessary to expose the second surface S2 of the conductive pillar 200 for the subsequent processes such as wire bonding.

Similar to the embodiment of FIG. 2A to FIG. 2M, in the present embodiment, the organic pillar 202 and the conductive layer 204 are used to form the conductive pillar 200 for allowing the top surface (or namely the inner surface) and the bottom surface (or namely the outer surface) of the conductive device substrate 40 to be in communication with each other. Thus, the objective of electrically connecting the top surface and the bottom surface of the conductive device substrate 40 can be achieved without the need to drill a hole and fill the hole with a conductive material, such that the process of manufacturing the conductive device substrate 40 is simplified, and the border space can be effectively reduced while maintaining the yield. In addition, because of the ductility of the substrate material layer 300 and the auxiliary substrate material layer 310, after the carrier substrate 100 is removed, the conductive device substrate 40 in the present embodiment is flexible, thus being applicable in more aspects.

Based on the above, the present disclosure uses the organic pillar and the conductive layer to form the conductive pillar for allowing the top surface (or namely the inner surface) and the bottom surface (or namely the outer surface) of the conductive device substrate to be in communication with each other. Thus, the objective of electrically connecting the top surface and the bottom surface of the conductive device substrate can be achieved without the need to drill a hole and fill the hole with a conductive material, such that the process of manufacturing the conductive device substrate is simplified, and the border space can be effectively reduced while maintaining the yield.

Even though the present disclosure has been disclosed with the above-mentioned embodiments, it is not limited thereto. Any person of ordinary skill in the art may make some changes and adjustments without departing from the spirit and scope of the present disclosure. Therefore, the scope of the present disclosure is defined in view of the appended claims.

What is claimed is:

1. A display panel, comprising:
a conductive device substrate, comprising:
a substrate material layer, comprising an organic material, and having an inner surface and an outer surface opposite to each other;
a conductive pillar, disposed in the substrate material layer, and having a first surface and a second surface opposite to each other, wherein the first surface of the conductive pillar is exposed on the inner surface of the substrate material layer, the second surface of the conductive pillar is exposed on the outer surface of the substrate material layer, and the conductive pillar further comprises:
an organic pillar, having a top surface and a bottom surface opposite to each other and a plurality of side surfaces connecting to the top surface and the bottom surface; and
a conductive layer, covering and in direct contact with the top surface of the organic pillar and the side surfaces of the organic pillar; and
a device layer, comprising at least one active device and disposed on the first surface of the conductive pillar and the substrate material layer, so as to be electrically connected to the first surface of the conductive pillar;
an opposite substrate, disposed opposite to the conductive device substrate, wherein the inner surface of the substrate material layer faces the opposite substrate;
a sealant, located between the conductive device substrate and the opposite substrate;
a display medium, located between the conductive device substrate, the opposite substrate, and the sealant;
a pixel electrode located on the conductive device substrate and facing the display medium;
a conductive adhesive layer, disposed on the second surface of the conductive pillar and being in contact with the second surface of the conductive pillar; and
an external device, disposed facing the outer surface of the substrate material layer, wherein the external device is disposed on one side of the conductive adhesive layer away from the conductive pillar and is in contact with the conductive adhesive layer,
wherein the conductive pillar, the conductive adhesive layer and the external device overlap the display medium in a vertical projection direction; and
wherein the pixel electrode and the at least one active device are entirely located between the inner surface of the substrate material layer and the opposite substrate.

2. The display panel according to claim 1, further comprising a carrier substrate, wherein the carrier substrate is disposed on the second surface of the conductive pillar.

3. The display panel according to claim 1, wherein the conductive device substrate further comprises an auxiliary substrate material layer, wherein the auxiliary substrate material layer is disposed on the second surface of the conductive pillar.

4. The display panel according to claim 1, wherein the organic material comprises polyimide or epoxy resin.

5. The display panel according to claim 1, wherein the external device comprises a chip, a flexible circuit board or a printed circuit board.

6. The display panel according to claim 1, wherein the conductive pillar is electrically connected to the least one active device.

7. The display panel according to claim 1, wherein the device layer further comprises least one scan line and least one the data line, and the conductive pillar is electrically connected to the data line or scan line.

8. The display panel according to claim 1, wherein a portion of the outer surface of the substrate material layer is exposed without being covered by any other layer.

9. The display panel according to claim 1, wherein the first surface of the conductive pillar does not overlap with the pixel electrode in the vertical projection direction.

10. The display panel according to claim 1, wherein:
the at least one active device comprises a gate electrode, a channel layer, a source electrode and a drain electrode;
the gate electrode is formed on the inner surface of the substrate material layer;
the pixel electrode is electrically connected to the drain electrode;
the source electrode is electrically connected to the conductive pillar; and
the drain electrode is separated from the source electrode.

11. The display panel according to claim 10, further comprising a barrier layer formed on the inner surface of the substrate material layer, wherein the barrier layer exposes at least one portions of the first surface of the conductive pillar such that the conductive pillar is electrically connected to the device layer via the at least one portions of the first surface of the conductive pillar being exposed by the barrier layer, and the gate electrode is located on the barrier layer.
